(19) United States
(12) Patent Application Publication
(10) Pub. No.: US 2024/0306496 A1
(43) Pub. Date: Sep. 12, 2024

(54) LUMINESCENT LAYER, LIGHT EMITTING DEVICE AND DISPLAY APPARATUS

(71) Applicant: BOE Technology Group Co., Ltd., Beijing (CN)

(72) Inventors: Yang Liu, Beijing (CN); Lixia Qiu, Beijing (CN); Yuqian Sun, Beijing (CN)

(73) Assignee: BOE Technology Group Co., Ltd., Beijing (CN)

(21) Appl. No.: 18/026,932

(22) PCT Filed: Apr. 22, 2022
(86) PCT No.: PCT/CN2022/088572

§ 371 Date: Mar. 17, 2023

(51) Int. Cl. H10K 85/60; H10K 50/11; H10K 101/00; H10K 101/30

(52) U.S. Cl. CPC H10K 85/6572; H10K 85/615; H10K 85/654; H10K 85/657; H10K 85/6574; H10K 50/11; H10K 2101/30; H10K 2101/90

(57) ABSTRACT

The present disclosure provides a luminescent layer, a light emitting device and a display apparatus. The luminescent layer includes: a host material including a hole-type host material and an electron-type host material, wherein by the effect of an external energy, the host material is configured to be capable of forming an exciplex; and a guest material being doped in the host material; wherein an absolute value of a difference between an energy value of a highest occupied molecular orbital HOMO of the hole-type host material and an energy value of a lowest unoccupied molecular orbital LUMO of the electron-type host material satisfies: 2.4 eV≤|HOMO-LUMO|≤3.2 eV. The luminescent layer according to the present disclosure, by using the energy-level configuration between the hole-type host material and the electron-type host material, can reduce the density of the triplet-state excitons, weaken TTA effect, and increase brightening voltage, thereby effectively ameliorating the interference between the pixels.

### TECHNICAL FIELD

The present disclosure relates to the technical field of displaying and, more particularly, to a luminescent layer, a light emitting device and a display apparatus.

### BACKGROUND

Currently, in the mass-produced OLED devices, the red-light devices are phosphorescent devices, and the red-light devices include a guest material and premixed double host materials.

The current red-light devices easily cause triplet exciton annihilation (TTA), whereby the devices have a serious efficiency roll-off with a large current density. Furthermore, the red-light devices easily cause a low brightening voltage, which results in problems such as interference between the pixels.

### SUMMARY

The embodiments of the present disclosure employ the following technical solutions:

In an aspect, an embodiment of the present disclosure provides a luminescent layer, wherein the luminescent layer includes:
a host material including a hole-type host material and an electron-type host material, wherein by the effect of an external energy, the host material is configured to be capable of forming an exciplex; and
a guest material being doped in the host material;
wherein an absolute value of a difference between an energy value of a highest occupied molecular orbital HOMO of the hole-type host material and an energy value of a lowest unoccupied molecular orbital LUMO of the electron-type host material satisfies: 2.4 eV≤|HOMO-LUMO|≤3.2 eV.

Optionally, an energy-level difference between a singlet-state energy level and a triplet-state energy level of the exciplex satisfies: 0 eV≤ΔEst≤0.3 eV.

Optionally, the host material includes at least one diplogen atom.

Optionally, the hole-type host material includes an indole-carbazole-type derivative, the indole-carbazole-type derivative includes a first six-membered ring, a second six-membered ring, a third six-membered ring and two nitrogen containing five-membered rings, the first six-membered ring is fused to the second six-membered ring via one of the nitrogen containing five-membered rings, and the second six-membered ring is fused to the third six-membered ring via the other of the nitrogen containing five-membered rings; and
the electron-type host material includes a triazine-type derivative, and the triazine-type derivative includes a triazinyl group, and a fourth six-membered ring, a fifth six-membered ring and a sixth six-membered ring that are bonded to the triazinyl group, respectively.

Optionally, the second six-membered ring and the fifth six-membered ring include a benzene ring;
the first six-membered ring, the third six-membered ring, the fourth six-membered ring and the sixth six-membered ring independently include at least one of a benzene ring, a benzene ring having a side chain, a nitrogen containing heterocycle having no substituent group, and a nitrogen containing heterocycle having the side chain; and
at least three carbon-hydrogen bonds in the first six-membered ring, the second six-membered ring, the third six-membered ring, the fourth six-membered ring, the fifth six-membered ring and the sixth six-membered ring other than the side chain are replaced by carbon-diplogen bonds.

Optionally, the indole-carbazole-type derivative further includes a first aryl group and a second aryl group, and the first aryl group and the second aryl group are bonded to nitrogen atoms of two nitrogen containing five-membered rings, respectively; and
at least four carbon-hydrogen bonds in the first aryl group and the second aryl group are replaced by carbon-diplogen bonds.

Optionally, the second six-membered ring and the fifth six-membered ring include a benzene ring;
the first six-membered ring, the third six-membered ring, the fourth six-membered ring and the sixth six-membered ring individually and independently include at least one of a benzene ring, a benzene ring having a side chain, a nitrogen containing heterocycle having no substituent group, and a nitrogen containing heterocycle having the side chain; and
at least one carbon-hydrogen bond in the side chain is replaced by a carbon-diplogen bond.

Optionally, the indole-carbazole-type derivative further includes a first aryl group and a second aryl group, and the first aryl group and the second aryl group are bonded to nitrogen atoms of two nitrogen containing five-membered rings, respectively; and
at least four carbon-hydrogen bonds in the first aryl group, the second aryl group and the side chain are replaced by carbon-diplogen bonds.

Optionally, a general structural formula of the indole-carbazole-type derivative is:

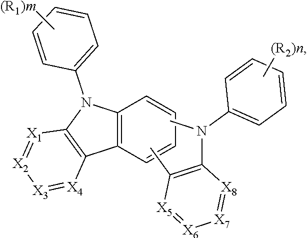

wherein X1-X8 are independently anyone of carbon-diplogen, carbon-R3 and nitrogen, wherein R3 is any one of phenyl, biphenyl, naphthyl, carbazole, dibenzofuran, dibenzothiophene, dimethyl fluorene, diphenyl fluorene, and C1-C10 alkyl;
R1 and R2 are independently any one of a single bond, phenyl, biphenyl, naphthyl, carbazole, dibenzofuran, dibenzothiophene, dimethyl fluorene, diphenyl fluorene, and C1-C10 alkyl; and
m and n are independently any one of 0, 1 and 2.

Optionally,

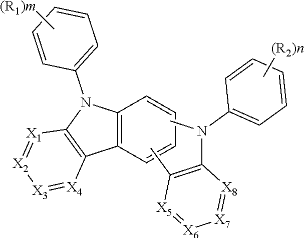

includes any one of

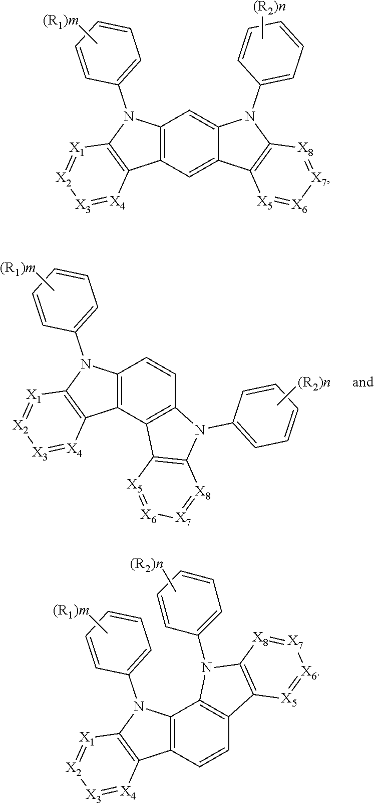

Optionally, both of an energy value of a highest occupied molecular orbital HOMO of the

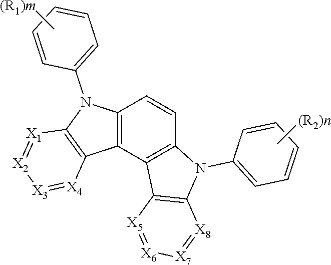

and an energy value of a highest occupied molecular orbital HOMO of the

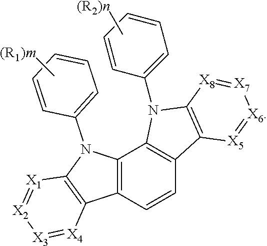

are less than an energy value of a highest occupied molecular orbital HOMO of the

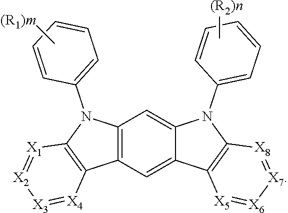

Optionally, in the

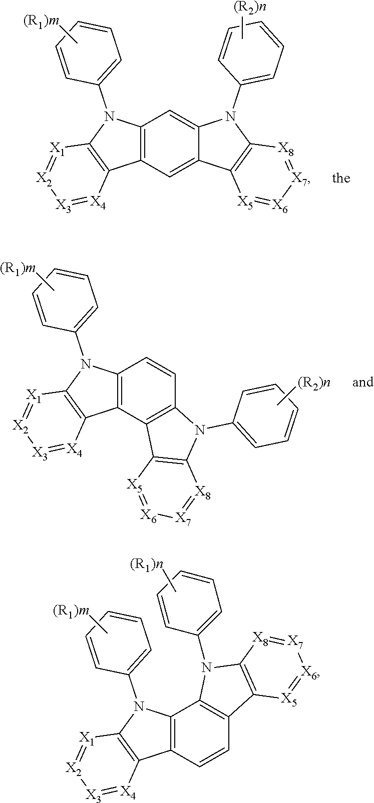

in any one of the general structural formulas, if all of the other groups are the same, an energy value of a highest occupied molecular orbital HOMO of a structure having the side chain is greater than an energy value of a highest occupied molecular orbital HOMO of a structure not having the side chain.

Optionally, wherein neighboring X groups in X1-X8 are fused to form any one of

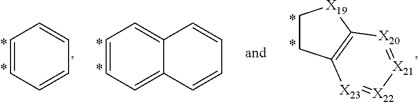

wherein * is a fusing position;
X19 is any one of carbon-R4R5, oxygen, sulphur and nitrogen-R6;
X24 and X29 are independently any one of oxygen, sulphur and nitrogen-R7; and
X20-X23 are independently any one of carbon-R8 and nitrogen;
wherein R4, R5, R6 and R8 are independently any one of a single bond, phenyl, biphenyl, naphthyl, carbazole, dibenzofuran, dibenzothiophene, dimethyl fluorene, diphenyl fluorene, and C1-C10 alkyl; and
R7 is phenyl.

Optionally, a general structural formula of the triazine-type derivative is:

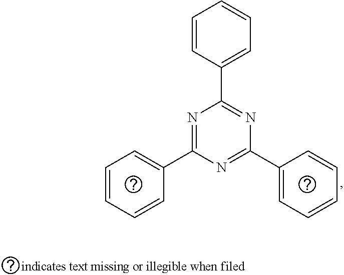 [SMILES: c1ccc(-c2nc(-c3ccccc3)nc(-c3ccccc3)n2)cc1]

wherein X9-X18 are independently any one of carbon-diplogen, carbon-R7 and nitrogen, wherein R7 is phenyl.

Optionally, in the general structural formula of the triazine-type derivative, if all of the other groups are the same, an energy value of a lowest unoccupied molecular orbital LUMO of a structure having the side chain is less than an energy value of a lowest unoccupied molecular orbital LUMO of a structure not having the side chain.

Optionally, neighboring X groups in X9-X18 are fused to form any one of

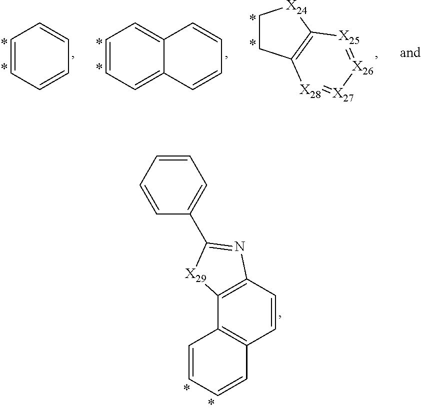

wherein * is a fusing position;
X24 and X29 are independently any one of oxygen, sulphur and nitrogen-R7; and
X25-X28 are independently any one of carbon-R8 and nitrogen;
wherein R8 is any one of a single bond, phenyl, biphenyl, naphthyl, carbazole, dibenzofuran, dibenzothiophene, dimethyl fluorene, diphenyl fluorene, and C1-C10 alkyl; and
R7 is phenyl.

Optionally, neighboring X groups in X19-X23 and neighboring X groups in X24-X28 are individually fused to form any one of

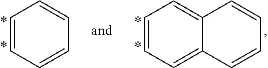 [SMILES: c1ccccc1 ; c1ccc2ccccc2c1]

respectively.

Optionally, a chemical structural formula of the indole-carbazole-type derivative includes any one of

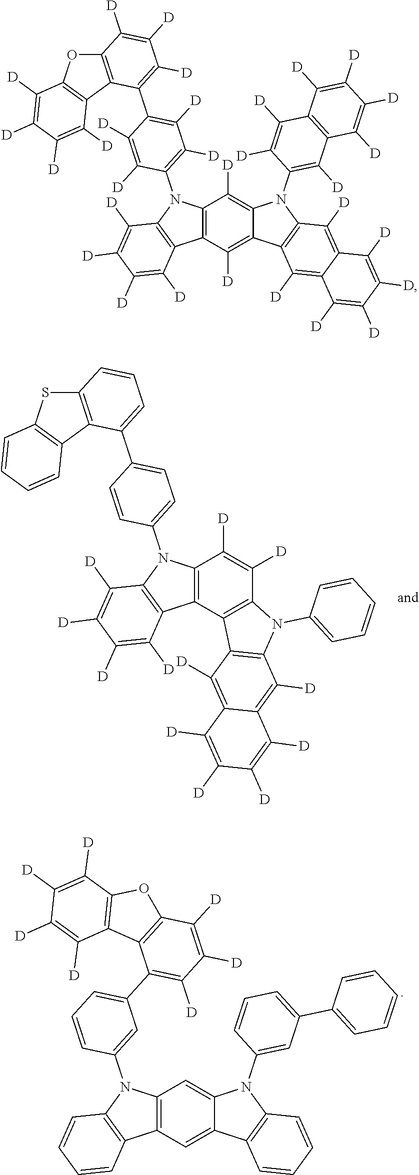

Optionally a chemical structural formula of the triazine-type derivative includes any one of

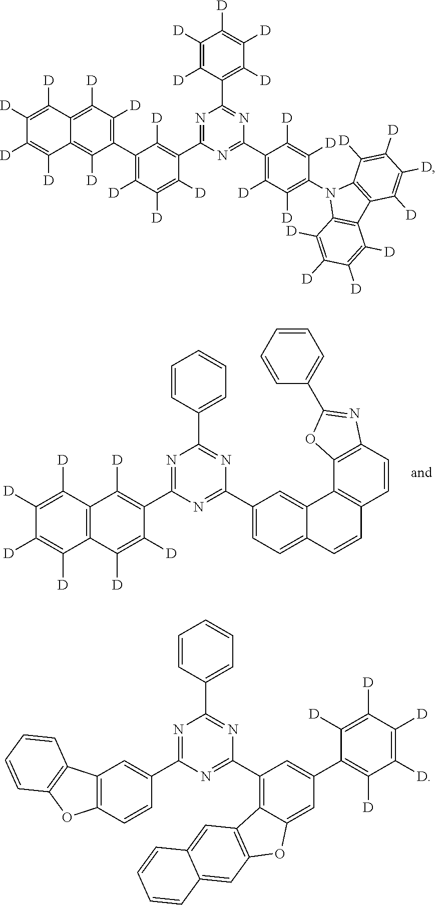

In another aspect, an embodiment of the present disclosure provides a light emitting device, wherein the light emitting device includes the luminescent layer stated above.

Optionally, the light emitting device further includes an anode and a cathode, and the luminescent layer is disposed between the anode and the cathode.

In yet another aspect, an embodiment of the present disclosure provides a display apparatus, wherein the display apparatus includes the light emitting device stated above.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are merely embodiments of the present disclosure, and a person skilled in the art can obtain other figures according to these figures without paying creative work.

FIG. 1 is a diagram showing the principle of the luminescence of a luminescent layer in the related art;

FIG. 2 is a schematic diagram of the variation of the exciton intensity with the distance between the luminescent layer and the interface of the electron blocking layer in the related art;

FIG. 3 is a diagram showing the principle of the luminescence of a luminescent layer according to an embodiment of the present disclosure;

FIG. 4 is a general structural formula of an indole-carbazole-type derivative according to an embodiment of the present disclosure:

FIG. 5 is a general structural formula of a triazine-type derivative according to an embodiment of the present disclosure;

FIG. 6 is a schematic structural diagram of a light emitting device according to an embodiment of the present disclosure; and

FIG. 7 is a schematic structural diagram of a display apparatus according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the drawings, the same reference numbers represent the same or similar components, and therefore the detailed description on them are omitted. Moreover, the drawings are merely schematic illustrations of the present disclosure, and are not necessarily drawn to scale.

In the embodiments of the present disclosure, unless stated otherwise, the meaning of “at least one” is “one or more”.

Unless stated otherwise in the context, throughout the description and the claims, the term “include” is interpreted as the meaning of opened containing, i.e., “including but not limited to”. In the description of the present disclosure, the terms “one embodiment”, “some embodiments”, “exemplary embodiments”, “example”. “specific example” or “some examples” are intended to indicate that specific features, structures, materials or characteristics related to the embodiment or example are included in at least one embodiment or example of the present disclosure. The illustrative indication of the above terms does not necessarily refer to the same one embodiment or example. Moreover, the specific features, structures, materials or characteristics may be included in any one or more embodiments or examples in any suitable manner.

In the embodiments of the present disclosure, terms such as “first”, “second”, “third”, “fourth”, “fifth” and “sixth” are used to distinguish identical items or similar items that have substantially the same functions and effects, merely in order to clearly describe the technical solutions of the embodiments of the present disclosure, and should not be construed as indicating or implying the degrees of importance or implicitly indicating the quantity of the specified technical features.

An embodiment of the present disclosure provides a luminescent layer, wherein the luminescent layer includes:
a host material including a hole-type host material and an electron-type host material, wherein by the effect of an external energy, the host material is configured to be capable of forming an exciplex; and
a guest material being doped in the host material;
wherein an absolute value of a difference between an energy value of a highest occupied molecular orbital HOMO of the hole-type host material and an energy value of a lowest unoccupied molecular orbital LUMO of the electron-type host material satisfies: 2.4 eV≤|HOMO-LUMO|≤3.2 eV.

The hole-type host material refers to an organic semiconductor material that, when holes are injected, by the effect of an electric field, can realize the directional, ordered and controllable migration of the charge carriers, thereby realizing charge transferring. The hole-type host material is not particularly limited herein. As an example, the hole-type host material may include an indole-carbazole-type derivative.

The electron-type host material refers to an organic semiconductor material that, when electrons are injected, by the effect of an electric field, can realize the directional, ordered and controllable migration of the charge carriers, thereby realizing charge transferring. The electron-type host material is not particularly limited herein. As an example, the electron-type host material may include a triazine-type derivative.

The range of the molar ratio of the hole-type host material to the electron-type host material is not particularly limited herein. As an example, the range of the molar ratio of the hole-type host material to the electron-type host material is 2:8-5:5. Accordingly, when the luminescent layer is applied to a device, the device can have a low brightening voltage, thereby effectively increasing the efficiency of the device, and improving the power consumption. Particularly, the molar ratio of the hole-type host material to the electron-type host material may be 2:8, 4:6, 5:5 and so on.

The range of the doped proportion of the guest material in the host material is not particularly limited herein. As an example, the range of the doped proportion of the guest material in the host material may be 1-10%. Particularly, the doped proportion may be 2%, 4%, 6%, 8%, 10% and so on.

The luminescent layer may be any one of a red-color luminescent layer, a green-color luminescent layer and a blue-color luminescent layer. In this case, the luminescent layer may be used for the light emission of a single color. The light emitting device may include all of the three types of the luminescent layers, the red-color luminescent layer, the green-color luminescent layer and the blue-color luminescent layer, and, certainly, may also include merely one type of the luminescent layers, for example, including merely a plurality of red-color luminescent layers, or including merely a plurality of green-color luminescent layers, or including merely a plurality of blue-color luminescent layers, which may be particularly determined according to practical demands. Herein the red-color luminescent layer is taken as an example for the description, and the luminescent layers of the other colors may refer to the red-color luminescent layer, and are not described particularly herein. The red-color luminescent layer includes the hole-type host material, the electron-type host material, and the guest material emitting a red light. The thickness of the red-color luminescent layer is not particularly limited herein. As an example, the range of the thickness of the red-color luminescent layer may be 20-70 nm. Particularly, the thickness of the red-color luminescent layer may be 20 nm, 40 nm, 50 nm or 70 nm.

The highest occupied molecular orbital (HOMO) refers to the molecular orbital having the highest energy among all of the molecular orbitals occupied by an electron. The energy value of the highest occupied molecular orbital is also referred to as the HOMO value.

The lowest unoccupied molecular orbital (LUMO) refers to the molecular orbital having the lowest energy among the molecular orbitals not occupied by an electron. The energy value of the lowest unoccupied molecular orbital is also referred to as the LUMO value.

The type of the external energy is not particularly limited herein. As an example, the external energy may include light, electricity and so on.

2.4 eV≤|HOMO-LUMO|≤3.2 eV. The |HOMO-LUMO| is not particularly limited herein. As an example, the |HOMO-LUMO| may be 2.4 eV, 2.5 eV, 2.7 eV, 2.9 eV, 3.0 eV, 3.2 eV and so on. Further, 2.5 eV≤|HOMO-LUMO|≤3.0 eV.

Currently, the mass-produced OLED (Organic Light Emitting Diode) red-light devices usually include a host material (RH) and a guest material (RD). The red-light host material is a premixed material, and includes a hole-type host material (RH-P type) and an electron-type host material (RH-N type). The hole-type host material and the electron-type host material can form an exciplex by the effect of an external energy such as light and electricity, and energy transfer is performed to the guest material via the exciplex, whereby the guest material has radiative transition to emit light.

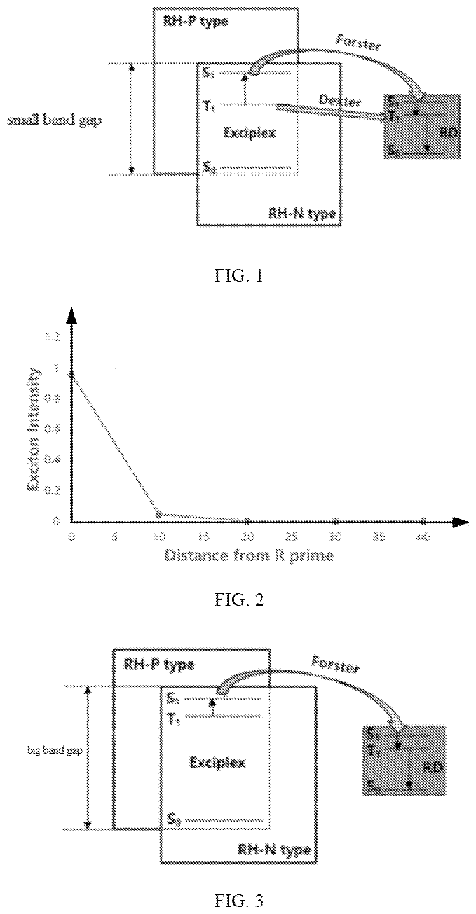

FIG. 1 is a diagram showing the principle of the luminescence of a red-light device in the related art. Referring to FIG. 1, in the red-light device, under electro-excitation, the RH-P type material and the RH-N type material form an exciplex. After the excitation, the holes and the electrons form excitons on the exciplex, wherein the energy levels of the excitons include the energy level S1 of the singlet-state excitons and the energy level T1 of the triplet-state excitons shown in FIG. 1. The energy level S1 of the singlet-state excitons is transferred from the exciplex to the guest material as a Foster energy, the energy level T1 of the triplet-state excitons is transferred from the exciplex to the guest material as a Dexter energy, and subsequently the guest material has radiative transition to emit light, thereby realizing the light emission of the light emitting device.

However, in the related art, the excitons formed after the red-light device is excited are transferred from the exciplex to the guest material mainly as a Dexter energy. Furthermore, referring to FIG. 2, the exciton-recombination region is concentrated at the side of the electron blocking layer (R prime layer), and therefore the concentration of the triplet-state excitons decreases more quickly, which easily causes triplet exciton annihilation (TTA), whereby the red-light device has a serious efficiency roll-off under a large current density, to cause the luminous efficiency of the red-light device to decrease obviously. FIG. 2 shows a schematic diagram of the variation of the exciton intensity in the luminescent layer with the distance between the luminescent layer and the interface of the R prime layer, wherein the horizontal coordinate represents the distance between the luminescent layer and the interface between the R prime layer and the luminescent layer with the unit of nm, wherein the interface between the R prime layer and the luminescent layer is used as the reference, or, in other words, the origin of coordinates is the interface between the R prime layer and the luminescent layer, and the vertical coordinate represents the exciton intensity.

Moreover, the energy-level configuration between the RH-P type material and the RH-N type material of the red-light device is unreasonable, and therefore the red-light device has a low brightening voltage, which easily results in problems such as interference between the pixels.

The embodiments of the present disclosure provide a luminescent layer, wherein the luminescent layer includes: a host material including a hole-type host material and an electron-type host material, wherein by the effect of an external energy, the host material is configured to be capable of forming an exciplex; and a guest material being doped in the host material, wherein an absolute value of a difference between an energy value of a highest occupied molecular orbital HOMO of the hole-type host material and an energy value of a lowest unoccupied molecular orbital LUMO of the electron-type host material satisfies: 2.4 eV≤|HOMO-LUMO|≤3.2 eV. Accordingly, in an aspect, by limiting the energy-level configuration between the hole-type host material and the electron-type host material in the luminescent layer, referring to FIG. 3, that can enable the exciplex formed by the hole-type host material and the electron-type host material by the effect of the external energy to have a high band gap, and effectively reduce the transition of the triplet-state excitons in the exciplex to the guest material, to reduce the Dexter energy transfer, and enhance the Forster energy transfer, thereby further reducing the density of the triplet-state excitons, and weakening the TTA effect. In another aspect, the high band gap of the exciplex formed by the hole-type host material and the electron-type host material by the effect of the external energy in the luminescent layer can increase the brightening voltage, thereby effectively ameliorating the interference between the pixels.

Optionally, an energy-level difference between a singlet-state energy level and a triplet-state energy level of the exciplex satisfies: 0 eV≤ΔEst≤0.3 eV. Accordingly, by limiting the energy-level configuration between the hole-type host material and the electron-type host material in the luminescent layer, that can enable the exciplex formed by the hole-type host material and the electron-type host material by the effect of the external energy to have a low ΔEst and a high band gap, and effectively reduce the transition of the triplet-state excitons in the exciplex to the guest material, to reduce the Dexter energy transfer, and enhance the Forster energy transfer, thereby further reducing the density of the triplet-state excitons, and weakening the TTA effect.

The particular numerical value of ΔEst is not limited herein. As an example, the particular numerical value of ΔEst may be 0 eV, 0.1 eV, 0.2 eV, 0.3 eV and so on. Further, 0 eV≤ΔEst≤=0.2 eV.

In the following, by testing RH-P1 (whose chemical formula is

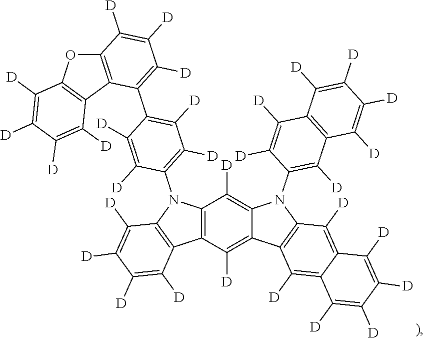 [SMILES: [2H]c1c([2H])c(-n2c3c([2H])c([2H])c([2H])c([2H])c3c3c([2H])c4c5c([2H])c6c([2H])c([2H])c([2H])c([2H])c6c([2H])c5n(-c5c([2H])c([2H])c6c([2H])c([2H])c([2H])c([2H])c6c5[2H])c4c([2H])c32)c([2H])c([2H])c1-c1c([2H])c([2H])c([2H])c2oc3c([2H])c([2H])c([2H])c([2H])c3c12]

RH-P2 (whose chemical formula is

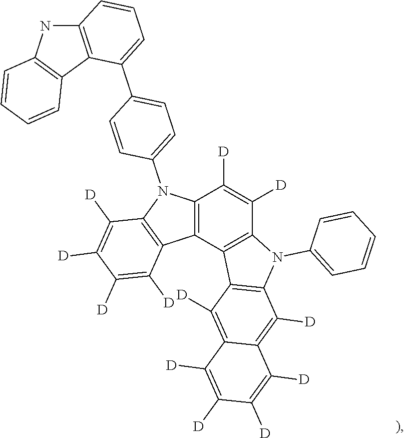 [SMILES: [2H]c1c([2H])c([2H])c2c([2H])c3c(c([2H])c2c1[2H])c1c2c4c([2H])c([2H])c([2H])c([2H])c4n(-c4ccc(-c5cccc6[nH]c7ccccc7c56)cc4)c2c([2H])c([2H])c1n3-c1ccccc1]

RH-P3 (whose chemical formula is

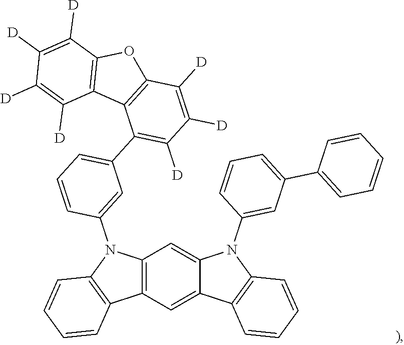 [SMILES: [2H]c1c([2H])c([2H])c2c(oc3c([2H])c([2H])c([2H])c(-c4cccc(-n5c6ccccc6c6cc7c8ccccc8n(-c8cccc(-c9ccccc9)c8)c7cc65)c4)c32)c1[2H]]

RH-P4 (whose chemical formula is

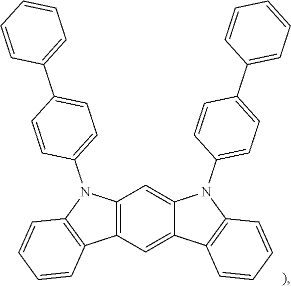 [SMILES: c1ccc(-c2ccc(-n3c4ccccc4c4cc5c6ccccc6n(-c6ccc(-c7ccccc7)cc6)c5cc43)cc2)cc1]

RH-N1 (whose chemical formula is

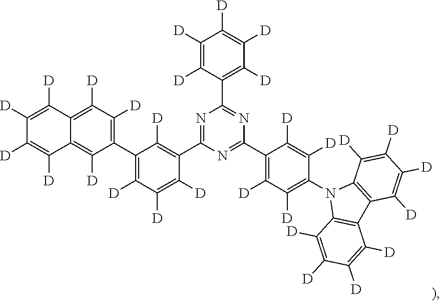 [SMILES: [2H]c1c([2H])c([2H])c(-c2nc(-c3c([2H])c([2H])c(-n4c5c([2H])c([2H])c([2H])c([2H])c5c5c([2H])c([2H])c([2H])c([2H])c54)c([2H])c3[2H])nc(-c3c([2H])c([2H])c([2H])c(-c4c([2H])c([2H])c5c([2H])c([2H])c([2H])c([2H])c5c4[2H])c3[2H])n2)c([2H])c1[2H]]

RH-N2 (whose chemical formula is

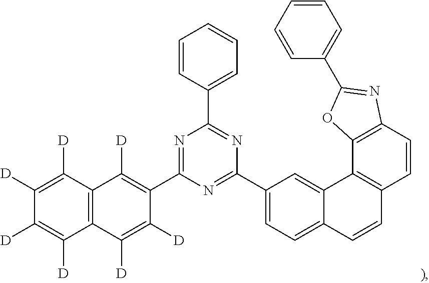 [SMILES: [2H]c1c([2H])c([2H])c2c([2H])c(-c3nc(-c4ccccc4)nc(-c4ccc5ccc6ccc7nc(-c8ccccc8)oc7c6c5c4)n3)c([2H])c([2H])c2c1[2H]]

RH-N3 (whose chemical formula is

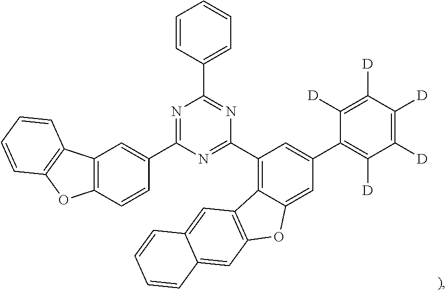 [SMILES: [2H]c1c([2H])c([2H])c(-c2cc(-c3nc(-c4ccccc4)nc(-c4ccc5oc6ccccc6c5c4)n3)c3c(c2)oc2cc4ccccc4cc23)c([2H])c1[2H]]

RH-N4 (whose chemical formula is

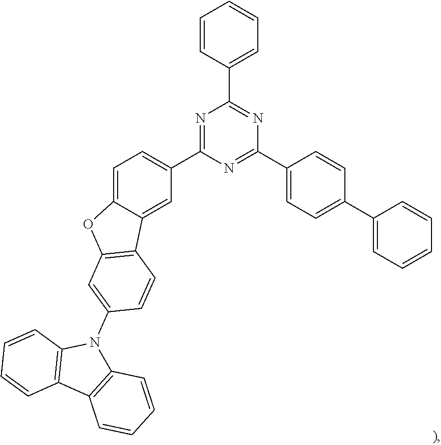 [SMILES: c1ccc(-c2ccc(-c3nc(-c4ccccc4)nc(-c4ccc5oc6cc(-n7c8ccccc8c8ccccc87)ccc6c5c4)n3)cc2)cc1]

the mixture of RH-P1 and RH-N1, the mixture of RH-P2 and RH-N2, the mixture of RH-P3 and RH-N3 and the mixture of RH-P4 and RH-N4, the numerical values of HOMO. LUMO, T1 and ΔEST are shown in Table 1 as follows.

TABLE 1

| | HOMO (eV) | LUMO (eV) | T1 (eV) | ΔEST (eV) |
|---|---|---|---|---|
| RH-P1 | 5.28 | 2.23 | 2.23 | 0.71 |
| RH-P2 | 5.33 | 2.28 | 2.26 | 0.68 |
| RH-P3 | 5.26 | 2.30 | 2.25 | 0.66 |
| RH-P4 | 5.21 | 2.46 | 2.28 | 0.69 |
| RH-N1 | 5.80 | 2.71 | 2.30 | 0.62 |
| RH-N2 | 5.76 | 2.72 | 2.26 | 0.64 |
| RH-N3 | 5.84 | 2.74 | 2.31 | 0.65 |
| RH-N4 | 5.92 | 2.86 | 2.28 | 0.71 |
| RH-P1: RH-N1 | — | — | 2.19 | 0.06 |
| RH-P2: RH-N2 | — | — | 2.16 | 0.15 |
| RH-P3: RH-N3 | — | — | 2.20 | 0.24 |
| RH-P4: RH-N4 | — | — | 2.11 | 0.36 |

In Table 1, RH-P1 to RH-P3 represent three different hole-type host materials according to the embodiments of the present disclosure, and RH-P4 represents a hole-type host material in a comparative example. RH-N1 to RH-N3 represent three different electron-type host materials according to the embodiments of the present disclosure, and RH-N4 represents an electron-type host material in a comparative example. T1 represents the energy level of the triplet-state excitons in RH-P1 to RH-P4 and RH-N1 to RH-N4. ΔEST represents the energy-level difference between the singlet state and the triplet state in RH-P1 to RH-P4 and RH-N1 to RH-N4.

It can be seen from Table 1 that, firstly, regarding the single-component host materials, in RH-P1 to RH-P4, all of the HOMO values of RH-P1 to RH-P3 are greater than the HOMO value of RH-P4, all of the LUMO values of RH-P1 to RH-P3 are less than the LUMO value of RH-P4, all of the T1 values of RH-P1 to RH-P3 are less than the T1 value of RH-P4, and all of the ΔEST values of RH-P1 to RH-P4 are greater than 0.3 eV. In RH-N1 to RH-N4, all of the HOMO values of RH-N1 to RH-N3 are less than the HOMO value of RH-N4, all of the LUMO values of RH-N1 to RH-N3 are less than the LUMO value of RH-N4, and all of the ΔEST values of RH-N1 to RH-N4 are greater than 0.3 eV.

Secondly, regarding the mixed host materials, all of T1s of the mixed host materials of the hole-type host materials and the electron-type host materials according to the embodiments of the present disclosure are greater than T1 of the mixed host material of the hole-type host material and the electron-type host material in the comparative example. All of the mixed host materials of the hole-type host materials and the electron-type host materials according to the embodiments of the present disclosure and the mixed host material of the hole-type host material and the electron-type host material in the comparative example have a low ΔEST, but ΔESTs of the mixed host materials of the hole-type host materials and the electron-type host materials according to the embodiments of the present disclosure are less than ΔEST of the mixed host material of the hole-type host material and the electron-type host material in the comparative example, and all of ΔESTs of the mixed host materials of the hole-type host materials and the electron-type host materials according to the embodiments of the present disclosure are less than 0.3 eV.

Optionally, the host material includes at least one diplogen atom.

That the host material includes at least one diplogen atom refers to that the host material includes merely one diplogen atom, or the host material includes two or more diplogen atoms.

The position of the diplogen atom is not particularly limited herein. If the host material includes merely one diplogen atom, the hole-type host material may include one diplogen atom, or the electron-type host material may include one diplogen atom. If the host material includes two or more diplogen atoms, both of the hole-type host material and the electron-type host material may include a diplogen atom, or merely the hole-type host material may include diplogen atoms, or merely the electron-type host material may include diplogen atoms.

Neither of RH-P4 and RH-N4 in Table 1 contains a diplogen atom, while all of RH-P1 to RH-P4 and RH-N1 to RH-N4 according to the embodiments of the present disclosure contain a diplogen atom. Therefore, the host material according to the embodiments of the present disclosure contains at least one diplogen atom. The deuteration can slow down molecule degradation, which can enable the exciplex formed by the hole-type host material and the electron-type host material by the effect of the external energy to have a high band gap. In an aspect, that effectively reduces the transition of the triplet-state excitons in the exciplex to the guest material, to reduce the Dexter energy transfer, and enhance the Forster energy transfer, thereby further reducing the density of the triplet-state excitons, and weakening the TTA effect. In another aspect, that can increase the brightening voltage, thereby effectively ameliorating the interference between the pixels.

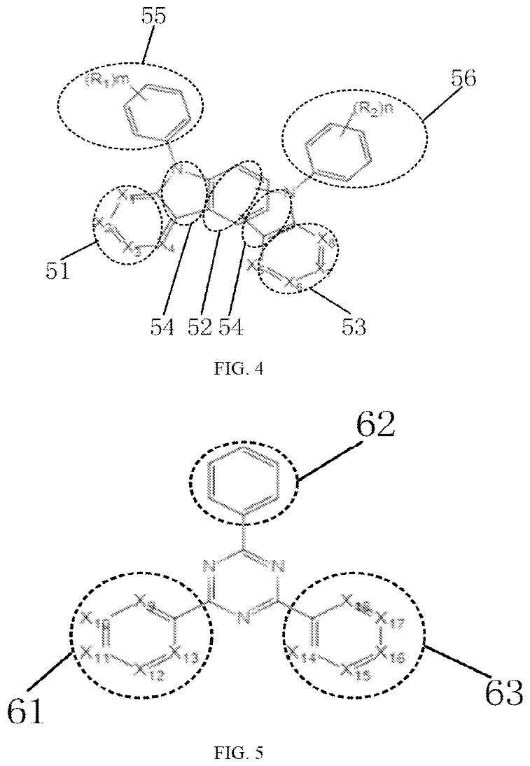

Optionally, the hole-type host material includes an indole-carbazole-type derivative. Referring to FIG. 4, the indole-carbazole-type derivative includes a first six-membered ring 51, a second six-membered ring 52, a third six-membered ring 53 and two nitrogen containing five-membered rings 54, the first six-membered ring 51 is fused to the second six-membered ring 52 via one of the nitrogen containing five-membered rings 54, and the second six-membered ring 52 is fused to the third six-membered ring 53 via the other of the nitrogen containing five-membered rings 54.

The electron-type host material includes a triazine-type derivative. Referring to FIG. 5, the triazine-type derivative includes a triazinyl group, and a fourth six-membered ring 61, a fifth six-membered ring 62 and a sixth six-membered ring 63 that are bonded to the triazinyl group, respectively.

The particular types of all of the first six-membered ring, the second six-membered ring and the third six-membered ring are not limited herein. As an example, the first six-membered ring, the second six-membered ring and the third six-membered ring may include a six-membered aromatic ring, in which case the six-membered aromatic ring may include a benzene ring having a substituent group and a benzene ring not having a substituent group. Alternatively, the first six-membered ring, the second six-membered ring and the third six-membered ring may include a six-membered heterocycle, in which case the heteroatom of the six-membered heterocycle may include a nitrogen atom and so on. Herein, the particular types of the first six-membered ring, the second six-membered ring and the third six-membered ring may be entirely the same, may also be entirely different, and may also be partially the same, which is particularly determined according to practical applications.

The particular quantity of the nitrogen atom in the nitrogen containing five-membered ring is not limited herein. As an example, the nitrogen containing five-membered ring may contain one nitrogen atom, as shown in FIG. 4. Alternatively, the nitrogen containing five-membered ring may contain two or more nitrogen atoms.

The particular types of all of the fourth six-membered ring, the fifth six-membered ring and the sixth six-membered ring are not limited herein. As an example, the fourth six-membered ring, the fifth six-membered ring and the sixth six-membered ring may include a six-membered aromatic ring, in which case the six-membered aromatic ring may include a benzene ring having a substituent group and a benzene ring not having a substituent group. Alternatively, the fourth six-membered ring, the fifth six-membered ring and the sixth six-membered ring may include a six-membered heterocycle, in which case the heteroatom of the six-membered heterocycle includes a nitrogen atom and so on. Herein, the particular types of the fourth six-membered ring, the fifth six-membered ring and the sixth six-membered ring may be entirely the same, may also be entirely different, and may also be partially the same, which is particularly determined according to practical applications.

Optionally, referring to FIG. 4 and FIG. 5, the second six-membered ring 52 and the fifth six-membered ring 62 include a benzene ring.

Referring to FIG. 4, the first six-membered ring 51, the third six-membered ring 53, the fourth six-membered ring 61 and the sixth six-membered ring 63 independently include at least one of a benzene ring, a benzene ring having a side chain, a nitrogen containing heterocycle having no substituent group, and a nitrogen containing heterocycle having the side chain.

At least three carbon-hydrogen bonds in the first six-membered ring, the second six-membered ring, the third six-membered ring, the fourth six-membered ring, the fifth six-membered ring and the sixth six-membered ring other than the side chain are replaced by carbon-diplogen bonds.

The particular type of the side chain is not limited herein. As an example, the side chain may include any one of a single bond, phenyl, biphenyl, naphthyl, carbazole, dibenzofuran, dibenzothiophene, dimethyl fluorene, diphenyl fluorene, and C1-C10 alkyl.

The particular quantity of the nitrogen atom in the nitrogen containing heterocycle having the side chain is not limited herein. As an example, the nitrogen containing heterocycle having the side chain contains one nitrogen atom, two nitrogen atoms, three nitrogen atoms, four nitrogen atoms or five nitrogen atoms.

Herein, the particular types of the first six-membered ring, the third six-membered ring, the fourth six-membered ring and the sixth six-membered ring may be entirely the same, may also be partially the same, and may also be entirely different, which is particularly determined according to practical applications.

In the indole-carbazole-type derivative according to the embodiments of the present disclosure, at least three carbon-hydrogen bonds in the first six-membered ring, the second six-membered ring, the third six-membered ring, the fourth six-membered ring, the fifth six-membered ring and the sixth six-membered ring other than the side chain are replaced by carbon-diplogen bonds. Referring to FIG. 4, the HOMO electron cloud mainly distributes in the group formed by the first six-membered ring 1, the second six-membered ring 2, the third six-membered ring 3 and two nitrogen containing five-membered rings 4. The hydrogen atoms belonging to the HOMO distribution unit may be preferentially replaced by diplogen atoms, and, therefore, when the hydrogen atoms in the skeleton except the side chain of the first six-membered ring 1, the second six-membered ring 2 and the third six-membered ring 3 are replaced by diplogen atoms, that can more effectively change the HOMO value. Likewise, referring to FIG. 5, the LUMO electron cloud mainly distributes in the group formed by the fourth six-membered ring 6, the fifth six-membered ring 7 and the sixth six-membered ring 8. The hydrogen atoms belonging to the LUMO distribution unit may be preferentially replaced by diplogen atoms, and, therefore, when the hydrogen atoms in the skeleton except the side chain of the fourth six-membered ring 6, the fifth six-membered ring 7 and the sixth six-membered ring 8 are replaced by diplogen atoms, that can more effectively change the LUMO value. Therefore, because at least three carbon-hydrogen bonds in the first six-membered ring, the second six-membered ring, the third six-membered ring, the fourth six-membered ring, the fifth six-membered ring and the sixth six-membered ring other than the side chain are replaced by carbon-diplogen bonds, which can slow down molecule degradation, that can enable the exciplex formed by the hole-type host material and the electron-type host material by the effect of the external energy to have a higher band gap. In an aspect, that more effectively reduces the transition of the triplet-state excitons in the exciplex to the guest material, to reduce the Dexter energy transfer, and further enhance the Forster energy transfer, thereby further reducing the density of the triplet-state excitons, and significantly weakening the TTA effect. In another aspect, that can more significantly increase the brightening voltage, thereby more effectively ameliorating the interference between the pixels.

Optionally, referring to FIG. 4, the indole-carbazole-type derivative further includes a first aryl group 55 and a second aryl group 56, and the first aryl group 55 and the second aryl group 56 are bonded to the nitrogen atoms of two nitrogen containing five-membered rings 54.

At least four carbon-hydrogen bonds in the first aryl group and the second aryl group are replaced by carbon-diplogen bonds.

The particular structures of the first aryl group and the second aryl group are not limited herein. As an example, the particular structures of the first aryl group and the second aryl group may include a phenyl not having a substituent, or may include a phenyl having a substituent, in which case the substituent may include any one of (R1)m and (R2)n shown in FIG. 4, wherein R1 and R2 are independently any one of a single bond, phenyl, biphenyl, naphthyl, carbazole, dibenzofuran, dibenzothiophene, dimethyl fluorene, diphenyl fluorene, and C1-C10 alkyl; and m and n are independently any one of 0, 1 and 2.

In the indole-carbazole-type derivative according to the embodiments of the present disclosure, the HOMO electron cloud mainly distributes in the group formed by the first six-membered ring, the second six-membered ring, the third six-membered ring and two nitrogen containing five-membered rings. The hydrogen atoms belonging to the HOMO distribution unit may be preferentially replaced by diplogen atoms, and the hydrogen atoms of the first aryl group and the second aryl group may also be replaced by diplogen atoms, with a priority lower than the priority with which the hydrogen atoms of the HOMO distribution unit are replaced by diplogen atoms. In this case, because at least four carbon-hydrogen bonds in the first aryl group and the second aryl group are replaced by carbon-diplogen bonds, that still can enable the exciplex formed by the hole-type host material and the electron-type host material by the effect of the external energy to have a high band gap. In an aspect, that effectively reduces the transition of the triplet-state excitons in the exciplex to the guest material, to reduce the Dexter energy transfer, and further enhance the Forster energy transfer, thereby further reducing the density of the triplet-state excitons, and weakening the TTA effect. In another aspect, that can increase the brightening voltage, thereby effectively ameliorating the interference between the pixels.

Optionally, referring to FIG. 4, the second six-membered ring 52 and the fifth six-membered ring 62 include a benzene ring.

Referring to FIG. 4, the first six-membered ring 51, the third six-membered ring 53, the fourth six-membered ring 61 and the sixth six-membered ring 63 individually and independently include at least one of a benzene ring, a benzene ring having a side chain, a nitrogen containing heterocycle having no substituent group, and a nitrogen containing heterocycle having the side chain.

At least one carbon-hydrogen bond in the side chain is replaced by a carbon-diplogen bond.

The particular type of the side chain is not limited herein. As an example, the side chain may include any one of a single bond, phenyl, biphenyl, naphthyl, carbazole, dibenzofuran, dibenzothiophene, dimethyl fluorene, diphenyl fluorene, and C1-C10 alkyl.

The particular quantity of the nitrogen atom in the nitrogen containing heterocycle having the side chain is not limited herein. As an example, the nitrogen containing heterocycle having the side chain contains one nitrogen atom, two nitrogen atoms, three nitrogen atoms, four nitrogen atoms or five nitrogen atoms.

Herein, the particular types of the first six-membered ring, the third six-membered ring, the fourth six-membered ring and the sixth six-membered ring may be entirely the same, may also be partially the same, and may also be entirely different, which is particularly determined according to practical applications.

In the indole-carbazole-type derivative according to the embodiments of the present disclosure, the HOMO electron cloud mainly distributes in the group formed by the first six-membered ring, the second six-membered ring, the third six-membered ring and two nitrogen containing five-membered rings. The hydrogen atoms belonging to the HOMO distribution unit may be preferentially replaced by diplogen atoms, and the hydrogen atoms of the side chain may also be replaced by diplogen atoms, with a priority lower than the priority that the hydrogen atoms of the LUMO distribution unit are replaced by diplogen atoms. Likewise, the LUMO electron cloud mainly distributes in the group formed by the fourth six-membered ring, the fifth six-membered ring and the sixth six-membered ring. The hydrogen atoms belonging to the LUMO distribution unit may be preferentially replaced by diplogen atoms, and the hydrogen atoms of the side chain may also be replaced by diplogen atoms, with a priority lower than the priority that the hydrogen atoms of the LUMO distribution unit are replaced by diplogen atoms. In this case, because at least one carbon-hydrogen bond in the side chain is replaced by a carbon-diplogen bond, which can slow down molecule degradation, that still can enable the exciplex formed by the hole-type host material and the electron-type host material by the effect of the external energy to have a high band gap. In an aspect, that effectively reduces the transition of the triplet-state excitons in the exciplex to the guest material, to reduce the Dexter energy transfer, and further enhance the Forster energy transfer, thereby further reducing the density of the triplet-state excitons, and weakening the TTA effect. In another aspect, that can increase the brightening voltage, thereby effectively ameliorating the interference between the pixels.

Optionally, referring to FIG. 4, the indole-carbazole-type derivative further includes a first aryl group 55 and a second aryl group 56, and the first aryl group 55 and the second aryl group 56 are bonded to the nitrogen atoms of two nitrogen containing five-membered rings 54, respectively.

At least four carbon-hydrogen bonds in the first aryl group, the second aryl group and the side chain are replaced by carbon-diplogen bonds.

The particular structures of the first aryl group and the second aryl group are not limited herein. As an example, the particular structures of the first aryl group and the second aryl group may include a phenyl not having a substituent, or may include a phenyl having a substituent, in which case the substituent may include any one of (R1)m and (R2)n shown in FIG. 4, wherein R1 and R2 are independently any one of a single bond, phenyl, biphenyl, naphthyl, carbazole, dibenzofuran, dibenzothiophene, dimethyl fluorene, diphenyl fluorene, and C1-C10 alkyl; and in and n are independently any one of 0, 1 and 2.

In the indole-carbazole-type derivative according to the embodiments of the present disclosure, the HOMO electron cloud mainly distributes in the group formed by the first six-membered ring, the second six-membered ring, the third six-membered ring and two nitrogen containing five-membered rings. The hydrogen atoms belonging to the HOMO distribution unit may be preferentially replaced by diplogen atoms, and the hydrogen atoms of the first aryl group, the second aryl group and the side chain may also be replaced by diplogen atoms, with a priority lower than the priority that the hydrogen atoms of the LUMO distribution unit are replaced by diplogen atoms. Likewise, the LUMO electron cloud mainly distributes in the group formed by the fourth six-membered ring, the fifth six-membered ring and the sixth six-membered ring. The hydrogen atoms belonging to the LUMO distribution unit may be preferentially replaced by diplogen atoms, and the hydrogen atoms of the first aryl group, the second aryl group and the side chain may also be replaced by diplogen atoms, with a priority lower than the priority that the hydrogen atoms of the LUMO distribution unit are replaced by diplogen atoms. In this case, because at least four carbon-hydrogen bonds in the first aryl group, the second aryl group and the side chain are replaced by carbon-diplogen bonds, which can slow down molecule degradation, that still can enable the exciplex formed by the hole-type host material and the electron-type host material by the effect of the external energy to have a high band gap. In an aspect, that effectively reduces the transition of the triplet-state excitons in the exciplex to the guest material, to reduce the Dexter energy transfer, and further enhance the Forster energy transfer, thereby further reducing the density of the triplet-state excitons, and weakening the TTA effect. In another aspect, that can increase the brightening voltage, thereby effectively ameliorating the interference between the pixels.

Optionally, a general structural formula of the indole-carbazole-type derivative is:

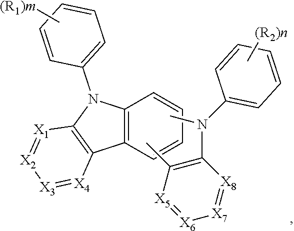

wherein X1-X8 are independently any one of carbon-diplogen, carbon-R3 and nitrogen, wherein R3 is any one of phenyl, biphenyl, naphthyl, carbazole, dibenzofuran, dibenzothiophene, dimethyl fluorene, diphenyl fluorene, and C1-C10 alkyl;
R1 and R2 are independently any one of a single bond, phenyl, biphenyl, naphthyl, carbazole, dibenzofuran, dibenzothiophene, dimethyl fluorene, diphenyl fluorene, and C1-C10 alkyl; and
m and n are independently any one of 0, 1 and 2.

Optionally,

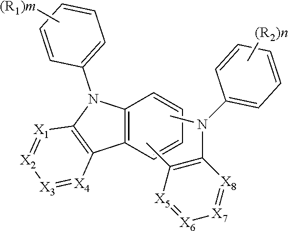

includes any one of

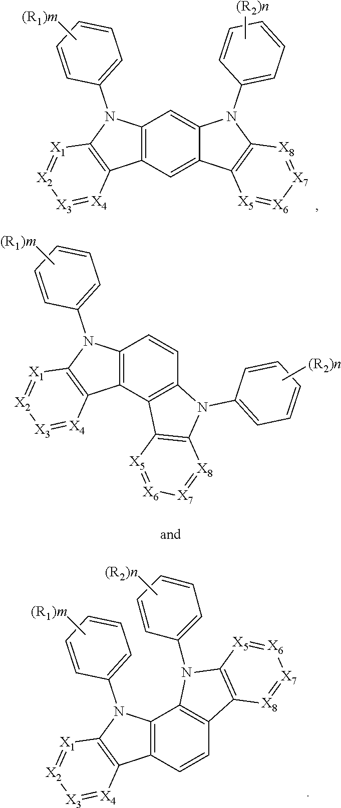

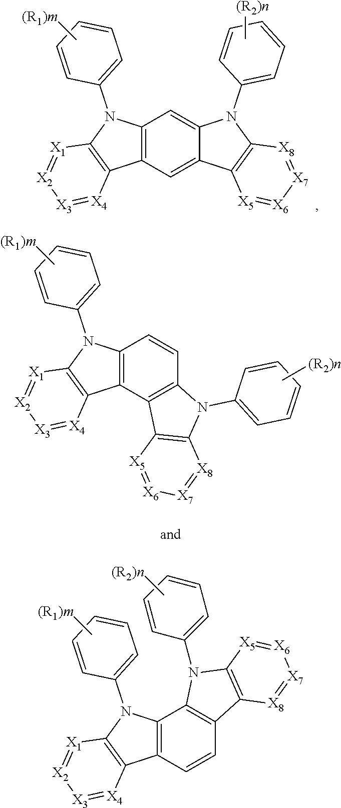

are three isomerides of

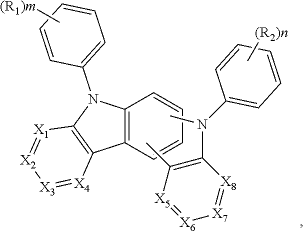

whereby various different indole-carbazole-type derivatives based on the general formula of those three isomerides can be obtained.

Optionally, both of an energy value of a highest occupied molecular orbital HOMO of the

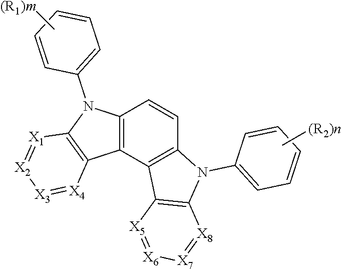

and an energy value of a highest occupied molecular orbital HOMO of the

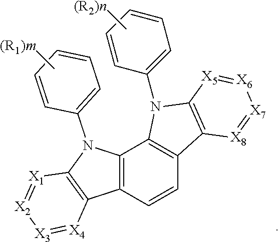

are less than an energy value of a highest occupied molecular orbital HOMO of the

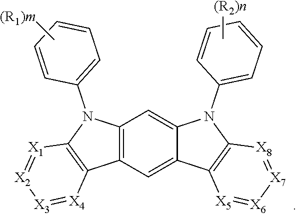

Accordingly, by adjusting the relative position of two nitrogen containing five-membered rings in the phenyl group, i.e., when the relative position of the nitrogen atoms of the two nitrogen containing five-membered rings in the phenyl group has three carbon atoms therebetween, the conjugative effect of the neighboring sections of the indolocarbazole can be changed, whereby the highest occupied molecular orbital HOMO has a highest energy value, a lowest triplet-state energy level, and a highest mobility.

By taking the case as an example in which, in the above general structural formula, all of X1-X8 are carbon-hydrogen bonds and both of m and n are 1, the energy values and so on of the highest occupied molecular orbitals HOMO of three indolocarbazole groups having the groups R1 and R2 will be described below. The general formulas of the three indolocarbazole groups having the groups R1 and R2 are

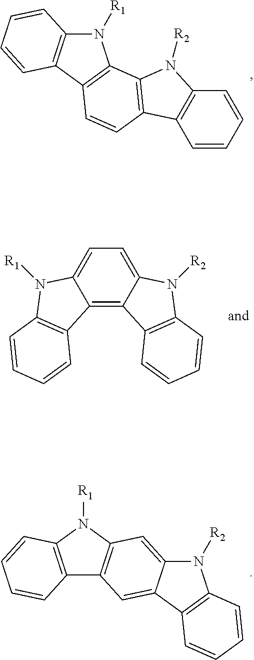

Because the highest occupied molecular orbital HOMO distributes at the indolocarbazole unit, by adjusting the structures of the general formulas, i.e., adjusting the connection position of the indolocarbazole, the conjugative effect of the neighboring sections of the indolocarbazole can be changed, whereby the highest occupied molecular orbital HOMO of

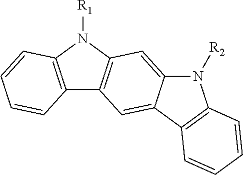

has a highest energy value, a lowest triplet-state energy level, and a highest mobility.

Optionally, in the

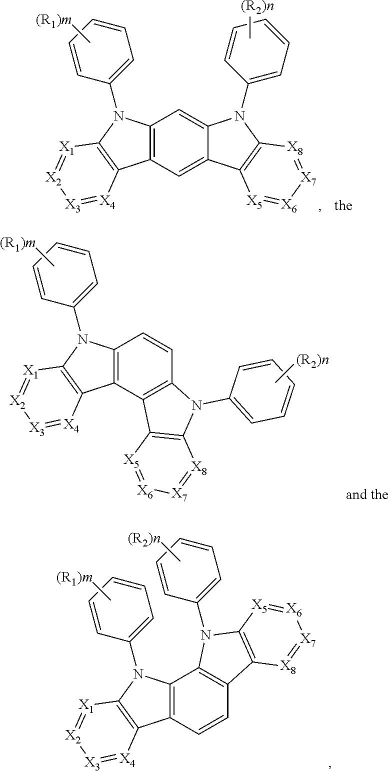

in any one of the general structural formulas, if all of the other groups are the same, an energy value of a highest occupied molecular orbital HOMO of a structure having the side chain is greater than an energy value of a highest occupied molecular orbital HOMO of a structure not having the side chain. Accordingly, by adding a substituent in the same one general structural formula, i.e., increasing the molecular weight of the structure of the same one general structural formula, the conjugative effect of the neighboring sections of the indolocarbazole can be changed, whereby the highest occupied molecular orbital HOMO has a highest energy value, a lowest triplet-state energy level, and a highest mobility.

By taking the case as an example in which, in the above general structural formula

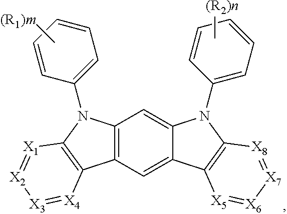

all of X1-X8 are carbon-hydrogen bonds and both of m and n are 1, the energy value and so on of the highest occupied molecular orbital HOMO of the group fused to one phenyl group will be described below. The general formula of the indolocarbazole group having the groups R1 and R2 is

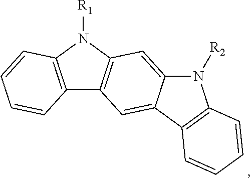

and the general formula of the indolocarbazole group having the groups R1 and R2 fused to one phenyl group is

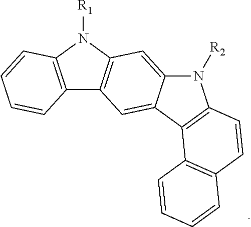

The conjugative effect of the neighboring sections of the indolocarbazole can be changed, whereby the highest occupied molecular orbital HOMO of

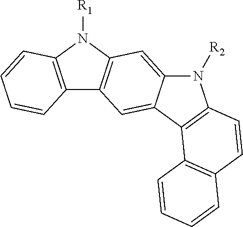

has a highest energy value, a lowest triplet-state energy level, and a highest mobility.

Optionally, neighboring X groups in X1-X8 are fused to form any one of

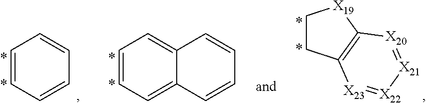

wherein * is a fusing position;
X19 is any one of carbon-R4R5, oxygen, sulphur and nitrogen-R6;
X24 and X29 are independently any one of oxygen, sulphur and nitrogen-R7; and
X20-X23 are independently anyone of carbon-R8 and nitrogen;
wherein R4, R5. R6 and R8 are independently any one of a single bond, phenyl, biphenyl, naphthyl, carbazole, dibenzofuran, dibenzothiophene, dimethyl fluorene, diphenyl fluorene, and C1-C10 alkyl, and
R7 is phenyl.

Optionally, a general structural formula of the triazine-type derivative is:

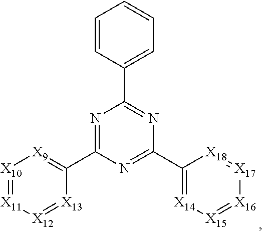

wherein X9-X18 are independently any one of carbon-diplogen, carbon-R7 and nitrogen, wherein R7 is phenyl.

Optionally, in the general structural formula of the triazine-type derivative, if all of the other groups are the same, an energy value of a lowest unoccupied molecular orbital LUMO of a structure having the side chain is less than an energy value of a lowest unoccupied molecular orbital LUMO of a structure not having the side chain. Accordingly, by adding a substituent in the same one general structural formula, i.e., increasing the molecular weight of the structure of the same one general structural formula, the conjugative effect of the group directly connected to the triazinyl group can be changed, whereby the lowest unoccupied molecular orbital LUMO has a lowest energy value, a lowest triplet-state energy level, and a highest mobility.

For example, when

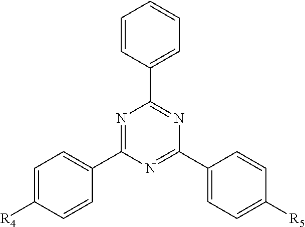

is fused to one phenyl group,

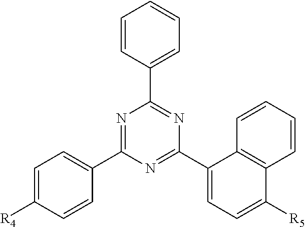

is obtained, which can change the conjugative effect of the group directly connected to the triazinyl group, whereby the lowest unoccupied molecular orbital LUMO of

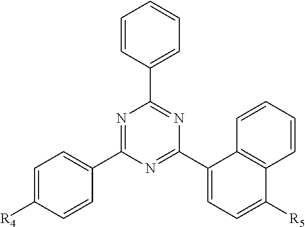

has a lowest energy value, a lowest triplet-state energy level, and a highest mobility.

Optionally, neighboring X groups in X9-X18 are fused to form any one of

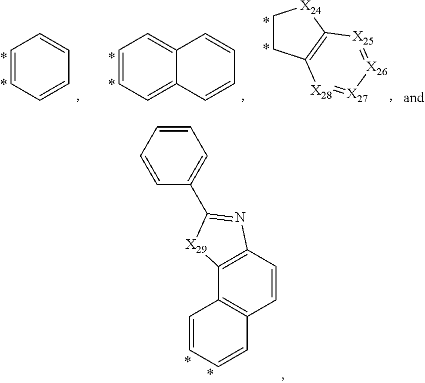

wherein * is a fusing position;
X24 and X29 are independently any one of oxygen, sulphur and nitrogen-R7; and
X25-X28 are independently any one of carbon-R8 and nitrogen;
wherein R8 is any one of a single bond, phenyl, biphenyl, naphthyl, carbazole, dibenzofuran, dibenzothiophene, dimethyl fluorene, diphenyl fluorene, and C1-C10 alkyl; and
R7 is phenyl.

Optionally, neighboring X groups in X19-X23 and neighboring X groups in X24-X28 are individually fused to form any one of

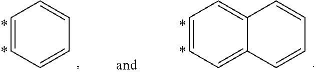 [SMILES: c1ccccc1 ; "," ; c1ccc2ccccc2c1 ; "."]

Optionally, a chemical structural formula of the indole-carbazole-type derivative includes any one of

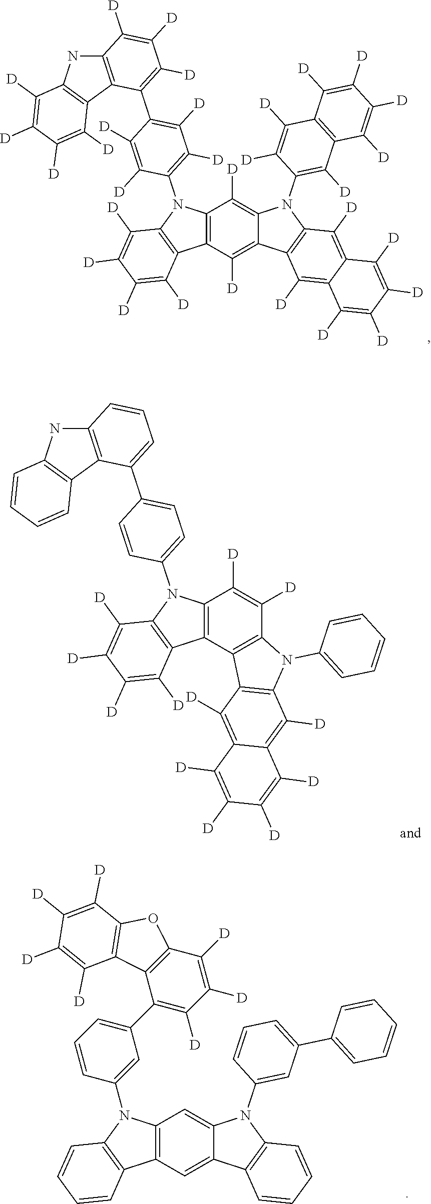

Optionally, a chemical structural formula of the triazine-type derivative includes any one of

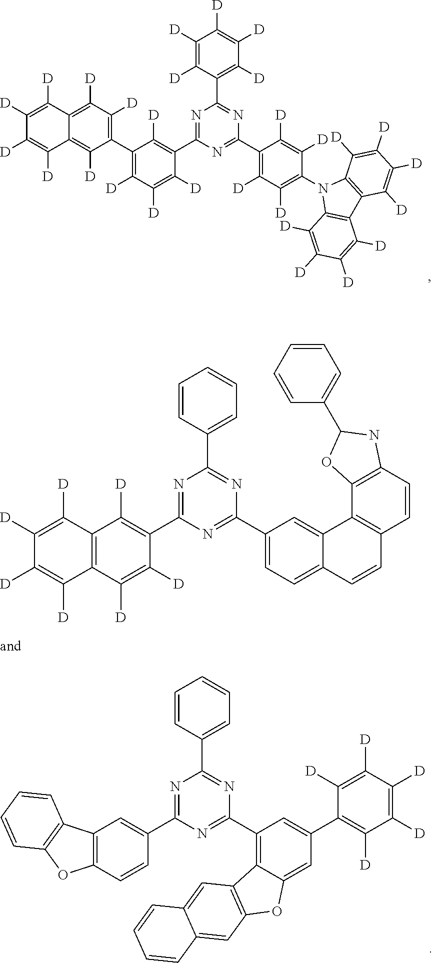 [SMILES: [2H]c1c([2H])c([2H])c(-c2nc(-c3c([2H])c([2H])c(-n4c5c([2H])c([2H])c([2H])c([2H])c5c5c([2H])c([2H])c([2H])c([2H])c54)c([2H])c3[2H])nc(-c3c([2H])c([2H])c([2H])c(-c4c([2H])c([2H])c5c([2H])c([2H])c([2H])c([2H])c5c4[2H])c3[2H])n2)c([2H])c1[2H] ; [2H]c1c([2H])c([2H])c2c([2H])c(-c3nc(-c4ccccc4)nc(-c4ccc5ccc6ccc7c(c6c5c4)OC(c4ccccc4)N7)n3)c([2H])c([2H])c2c1[2H] ; [2H]c1c([2H])c([2H])c(-c2cc(-c3nc(-c4ccccc4)nc(-c4ccc5oc6ccccc6c5c4)n3)c3c(c2)oc2cc4ccccc4cc23)c([2H])c1[2H]]

In another aspect, an embodiment of the present disclosure provides a light emitting device, wherein the light emitting device includes the luminescent layer stated above.

The process for fabricating the light emitting device is not particularly limited herein. As an example, the film layers of the light emitting device may be fabricated by vacuum vapor deposition.

The type of the light emitting device is not particularly limited herein. As an example, the light emitting device may include a top-emission-type light emitting device or a bottom-emission-type light emitting device.

The light emitting device according to the embodiments of the present disclosure, in an aspect, by limiting the energy-level configuration between the hole-type host material and the electron-type host material in the luminescent layer, can enable the exciplex formed by the hole-type host material and the electron-type host material by the effect of the external energy to have a high band gap, and effectively reduce the transition of the triplet-state excitons in the exciplex to the guest material, to enhance the Forster energy transfer, thereby further reducing the density of the triplet-state excitons, and weakening the TTA effect. In another aspect, the high band gap of the exciplex formed by the hole-type host material and the electron-type host material by the effect of the external energy in the luminescent layer can increase the brightening voltage, thereby effectively ameliorating the interference between the pixels.

The range of the brightening voltage of the light emitting device is not particularly limited herein. As an example, the range of the brightening voltage of the light emitting device is 1.8V-2.2V, in which case the brightening voltage is the voltage corresponding to the brightness of 1 nit. Particularly, the brightening voltage may be 1.8V, 1.9V, 2.0V, 2.1 V, 2.2V and so on.

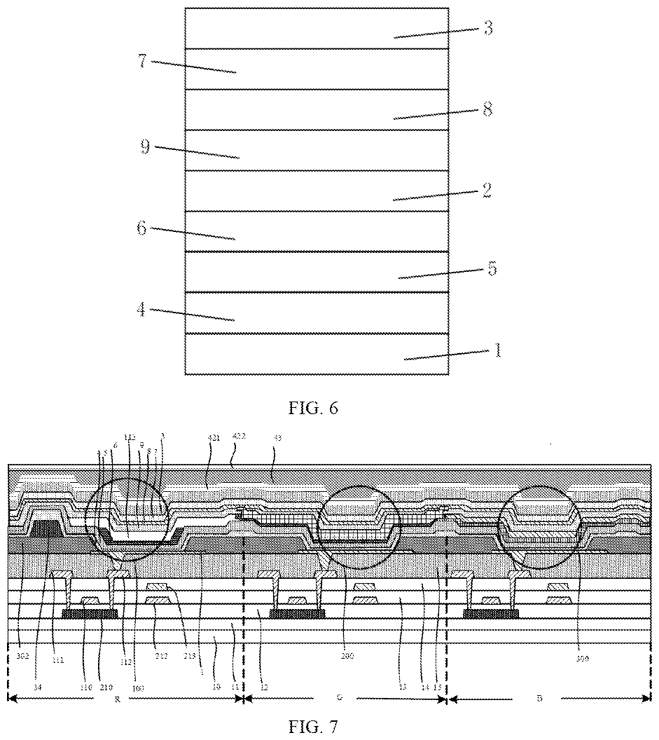

Optionally, referring to FIG. 6, the light emitting device further includes an anode 1 and a cathode 3, and the luminescent layer 2 is disposed between the anode 1 and the cathode 3.

The material of the anode is not particularly limited herein. As an example, the material of the anode may include ITO (Indium Tin Oxides).

The process for fabricating the anode is not particularly limited herein. As an example, the process may include performing sonication to a glass plate having ITO in deionized water, and subsequently drying the glass plate at 100° C., to obtain the anode.

Optionally, referring to FIG. 6, the light emitting device further includes a hole injection layer 4, a hole transporting layer 5 and an electron blocking layer 6 that are disposed between the anode 1 and the luminescent layer 2, and an electron injection layer 7, an electron transporting layer 8 and a hole blocking layer 9 that are disposed between the cathode 3 and the luminescent layer 2.

Referring to FIG. 6, the hole injection layer 4 is disposed between the anode 1 and the hole transporting layer 5, and the hole transporting layer 5 is disposed between the hole injection layer 4 and the electron blocking layer 6. The electron injection layer 7 is disposed between the cathode 3 and the electron transporting layer 8, and the electron transporting layer 8 is disposed between the electron injection layer 7 and the hole blocking layer 9.

The material of the electron blocking layer may be a substance having the characteristic of hole transferring, for example, any one of an arylamine-type compound, dimethyl fluorene, and a carbazole material and a derivative thereof. As an example, the material of the electron blocking layer may be CBP, whose chemical structural formula is

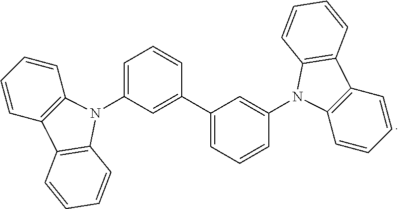 [SMILES: c1cc(-c2cccc(-n3c4ccccc4c4ccccc43)c2)cc(-n2c3ccccc3c3ccccc32)c1]

The thickness of the electron blocking layer is not particularly limited herein. As an example, the thickness of the electron blocking layer may be 80 nm.

The material of the hole blocking layer may be an aromatic heterocyclic compound, for example, any one or combination of two or more of benzimidazole, triazine, pyrimidine, pyridine, pyrazine, quinoxaline, quinoline, diazole, diazephosphoracyclopentadiene, phosphine oxide, aromatic ketone, lactam and borane and derivatives thereof. As an example, the material of the hole blocking layer may be TPBI, wherein the name in English of TPBI is 1,3,5-tris(1-phenyl-1H-benzimidazol-2-yl)benzene, and the chemical structural formula is

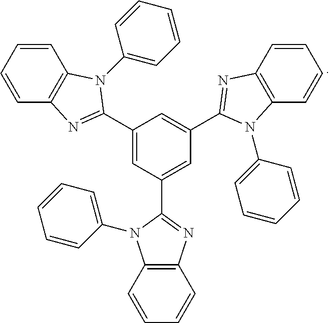 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron blocking layer can block the electrons in the luminescent layer from going out of the luminescent layer, to ensure that more electrons recombine with the holes in the luminescent layer, thereby increasing the quantity of the excitons, and in turn increasing the luminous efficiency. The hole blocking layer can block the holes in the luminescent layer from going out of the luminescent layer, to ensure that more holes recombine with the electrons in the luminescent layer, thereby increasing the quantity of the excitons, and in turn increasing the luminous efficiency.

The material of the hole injection layer may be an inorganic oxide, a P-type dopant of a strong electrophilic system and a dopant of a hole transporting material, for example, hexacyanohexazatriphenylene; 2,3,5,6-tetrafluoro-7.7′,8,8′-tetracyanodimethyl-p-benzoquinone (F4TCNQ), whose chemical structural formula is

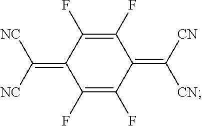 [SMILES: N#CC(C#N)=c1c(F)c(F)c(=C(C#N)C#N)c(F)c1F]

1,2,3-tri[(cyano)(4-cyano-2,3,5,6-tetrafluorophenyl)methylene]cyclopropanϵ: 4,4′,4″-tri[phenyl(m-methylphenyl)amino]triphenylamine (m-MTDATA), whose chemical structural formula is

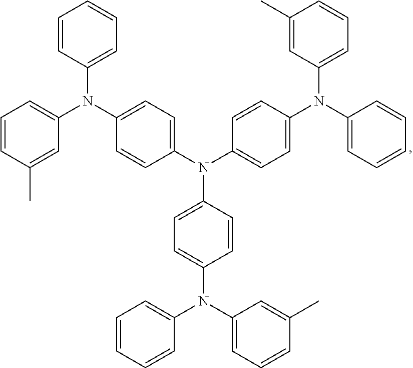 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

and so on.

The material of the hole transporting layer may be a substance having the characteristic of hole transferring, for example, any one of an arylamine-type compound, dimethyl fluorene, and a carbazole material and a derivative thereof. As an example, the material of the hole transporting layer may be m-MTDATA.

The material of the electron injection layer may be an alkali metal or a metal, for example, LiF, Yb, Mg, Ca and compounds thereof. Herein, the name in English of LiF is lithium fluoride. The name in English of Yb is ytterbium.

The material of the electron transporting layer may be an aromatic heterocyclic compound, for example, any one or combination of two or more of benzimidazole, triazine, pyrimidine, pyridine, pyrazine, quinoxaline, quinoline, diazole, diazephosphoracyclopentadiene, phosphine oxide, aromatic ketone, lactam and borane and derivatives thereof. As an example, the material of the electron transporting layer may be BCP, wherein the name in English of BCP is 2,9-dimethyl-4,7-biphenyl-1,10-phenanthroline.

In the following, by applying the luminescent layers formed by using the materials of Example 1 (RH-P1: RH-N1), Example 2 (RH-P2: RH-N2), Example 3 (RH-P3: RH-N3) and Comparative Example 1 (RH-P4: RH-N4) individually to the light emitting device, the structures of the light emitting devices shown in Table 2 are obtained as follows.

TABLE 2

| | | hole | hole | electron | | hole | electron | electron | |
|---|---|---|---|---|---|---|---|---|---|
| serial | | injection | transporting | blocking | luminescent | blocking | transporting | injection | |
| number | anode | layer | layer | layer | layer | layer | layer | layer | cathode |
| Example 1 | ✓ | ✓ | ✓ | ✓ | RH-P1:RH-N1 | ✓ | ✓ | ✓ | ✓ |
| | | | | | (4:6):RD (2%) | | | | |
| | | | | | 40 nm | | | | |
| Example 2 | ✓ | ✓ | ✓ | ✓ | RH-P2:RH-N2 | ✓ | ✓ | ✓ | ✓ |
| | | | | | (4:6):RD (2%) | | | | |
| | | | | | 40 nm | | | | |
| Example 3 | ✓ | ✓ | ✓ | ✓ | RH-P3:RH-N3 | ✓ | ✓ | ✓ | ✓ |
| | | | | | (4:6):RD (2%) | | | | |
| | | | | | 40 nm | | | | |
| Comparative | ✓ | ✓ | ✓ | ✓ | RH-P4:RH-N4 | ✓ | ✓ | ✓ | ✓ |
| Example 1 | | | | | (4:6):RD (2%) | | | | |
| | | | | | 40 nm | | | | |

In Table 2 ✓ represents that the light emitting device has that film layer; RH-P1: RH-N(4:6) represents the ratio of the bole-type host material to the electron-type host material; RD (2%) represents the doped proportion of the guest material in the host material; and 40 nm represents the thickness of the luminescent layer.

Performance tests are performed to the light emitting devices shown in Table 2, and the performance parameter values shown in Table 3 are obtained as follows.

TABLE 3

| serial | V | efficiency | CIE | CIE | LT95 | Von | efficiency |
|---|---|---|---|---|---|---|---|
| number | (V) | (Cd/A) | x | y | (h) | (V) | roll-off |
| Example 1 | 100% | 106% | 0.68 | 0.31 | 128% | 104% | 5.8% |
| Example 2 | 101% | 104% | 0.68 | 0.31 | 119% | 106% | 6.2% |
| Example 3 | 98% | 105% | 0.68 | 0.31 | 116% | 105% | 5.4% |
| Comparative | 100% | 100% | 0.68 | 0.31 | 100% | 100% | 10.1% |
| Example 1 | | | | | | | |

In Table 3. V represents the voltage loaded on the light emitting device-: CIE x represents the x value in the chromaticity coordinate, and CIE y represents the y value in the chromaticity coordinate; LT95 represents the duration required by the initial brightness of the light emitting device to decrease to the brightness of 95% of the initial brightness: Von represents the brightening voltage of the light emitting device; and efficiency roll-off represents the proportion of the value of the efficiency decrease with the increasing of the voltage loaded on the light emitting device accounting for the initial efficiency value.

It can be obtained from Table 3 that all of the light emitting devices formed by using the materials according to the present disclosure, as compared with the light emitting device formed by using the materials in the comparative example, have a higher luminous efficiency, a longer life, a higher brightening voltage and a lower efficiency roll-off. The efficiency roll-off of the brightness of 1 nit and the efficiency roll-off of the brightness of 600 nits are 3%-10%.

It should be noted that none of the numerical values of the voltage, the efficiency, the life, the brightening voltage and the efficiency roll-off in Table 3 is the actual numerical value. Here taking the voltage as an example for the description, assuming that the voltage of the light emitting device fabricated by using the luminescent layer formed in the Example 2 that is actually measured is 1V, then the voltage of the light emitting device fabricated by using the luminescent layer formed in the Example 2 that is actually measured is 1.01V. All of the other parameters follow that example, which is not discussed herein further.

The light emitting device may be applied to a display apparatus. The particular structure of the display apparatus is not limited herein.

As an example, the display apparatus may include a displaying base plate and the light emitting device. The displaying base plate includes a plurality of pixel units that are arranged in an array. The light emitting device includes a red-color light emitting device, a green-color light emitting device and a blue-color light emitting device that are arranged in an array. Each of the pixel units includes a red-color sub-pixel, a green-color sub-pixel and a blue-color sub-pixel. The red-color sub-pixel is electrically connected to the red-color light emitting device, the green-color sub-pixel is electrically connected to the green-color light emitting device, and the blue-color sub-pixel is electrically connected to the blue-color light emitting device.

Referring to FIG. 7, the red-color sub-pixel is electrically connected to the red-color light emitting device 100, the green-color sub-pixel is electrically connected to the green-color light emitting device 200, and the blue-color sub-pixel is electrically connected to the blue-color light emitting device 300. Referring to FIG. 7, the particular structure will be described by taking the leftmost red-color sub-pixel as an example. The red-color sub-pixel includes: a buffer layer 11, an active layer 210, a gate insulation layer 12, a gate metal layer (including a gate electrode 110 and a first electrode 212), an insulation layer 13, an electrode layer (including a second electrode 213), an inter-layer-medium layer 14, a source-drain metal layer (including a source electrode 111 and a drain electrode 112), a planarization layer 15 and a pixel definition layer 302 that are located on a substrate 10 and are sequentially arranged in layer configuration. The first electrode 212 and the second electrode 213 are used to form a storage capacitor. The pixel definition layer 302 includes an opening, the red-color light emitting device 100 is disposed in the opening, and the anode 1 of the red-color light emitting device 100 is electrically connected to the drain electrode 112 of the thin-film transistor. The displaying base plate further includes a separator 34 located on the pixel definition layer 302. It should be noted that, in the displaying base plate, the spacer may be disposed on a part of the pixel definition layer, and may also be disposed on the whole pixel definition layer, which is not limited herein.

The red-color light emitting device 100 includes the anode 1, and the hole injection layer 4, the hole transporting layer 5, the electron blocking layer 6, a red-color luminescent layer 113, the hole blocking layer 9, the electron transporting layer 8, the electron injection layer 7 and the cathode 3 that are located on the anode 1 and are sequentially arranged in layer configuration.

It should be noted that the materials of the luminescent layers of the green-color light emitting device 200 and the blue-color light emitting device 300 shown in FIG. 7 are different from the material of the luminescent layer of the red-color light emitting device 100. The luminescent layer of the green-color light emitting device is used to emit a green light, the luminescent layer of the blue-color light emitting device is used to emit a blue light, and the luminescent layer of the red-color light emitting device is used to emit a red light. Moreover, the materials of the electron blocking layers of the green-color light emitting device and the blue-color light emitting device are different from the material of the electron blocking layer of the red-color light emitting device. Except for the luminescent layers and the electron blocking layers, all of the other film layers of the green-color light emitting device and the blue-color light emitting device are the same as those of the red-color light emitting device, and are not discussed herein further.

Referring to FIG. 7, the display apparatus may further include a first inorganic layer 421, an organic layer 43 and a second inorganic layer 422 that cover the light emitting device. The first inorganic layer 421, the organic layer 43 and the second inorganic layer 422 can serve for packaging, to protect the light emitting device, and prolong the service life.

In yet another aspect, an embodiment of the present disclosure provides a display apparatus, wherein the display apparatus includes the light emitting device stated above.

The display apparatus may be a flexible display apparatus (also referred to as a flexible screen), and may also be a rigid display apparatus (i.e., a display screen that cannot be bent), which is not limited herein. The display apparatus may be an OLED display apparatus, and may also be an LCD (Liquid-Crystal Display) display apparatus. The display apparatus may be any product or component having a displaying function, such as a television set, a digital camera, a mobile phone and a tablet personal computer. The display apparatus may also be applied in fields such as identity identification and medical equipment, and the products that have already been promoted or have a good prospect of promotion include security identity authentication, smart door locks, medical video collection and so on. The display apparatus has the advantages such as a significantly weakened TTA effect, an increased brightening voltage, a lower interference between the pixels, a good effect of displaying, a long life, a high stability, a high contrast, a good imaging quality, a high product quality and so on.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A luminescent layer, wherein the luminescent layer comprises:
a host material comprising a hole-type host material and an electron-type host material, wherein by the effect of an external energy, the host material is configured to be capable of forming an exciplex; and
a guest material being doped in the host material;
wherein an absolute value of a difference between an energy value of a highest occupied molecular orbital HOMO of the hole-type host material and an energy value of a lowest unoccupied molecular orbital LUMO of the electron-type host material satisfies: 2.4 eV≤|HOMO-LUMO|≤3.2 eV.

2. The luminescent layer according to claim 1, wherein an energy-level difference between a singlet-state energy level and a triplet-state energy level of the exciplex satisfies: 0 eV≤ΔEst≤0.3 eV.

3. The luminescent layer according to claim 1, wherein the host material comprises at least one diplogen atom.

4. The luminescent layer according to claim 3, wherein the hole-type host material comprises an indole-carbazole-type derivative, the indole-carbazole-type derivative comprises a first six-membered ring, a second six-membered ring, a third six-membered ring and two nitrogen containing five-membered rings, the first six-membered ring is fused to the second six-membered ring via one of the nitrogen containing five-membered rings, and the second six-membered ring is fused to the third six-membered ring via the other of the nitrogen containing five-membered rings; and
the electron-type host material comprises a triazine-type derivative, and the triazine-type derivative comprises a triazinyl group, and a fourth six-membered ring, a fifth six-membered ring and a sixth six-membered ring that are bonded to the triazinyl group, respectively.

5. The luminescent layer according to claim 4, wherein the second six-membered ring and the fifth six-membered ring comprise a benzene ring;
the first six-membered ring, the third six-membered ring, the fourth six-membered ring and the sixth six-membered ring independently comprise at least one of a benzene ring, a benzene ring having a side chain, a nitrogen containing heterocycle having no substituent group, and a nitrogen containing heterocycle having the side chain; and
at least three carbon-hydrogen bonds in the first six-membered ring, the second six-membered ring, the third six-membered ring, the fourth six-membered ring, the fifth six-membered ring and the sixth six-membered ring other than the side chain are replaced by carbon-diplogen bonds.

6. The luminescent layer according to claim 4, wherein the indole-carbazole-type derivative further comprises a first aryl group and a second aryl group, and the first aryl group and the second aryl group are bonded to nitrogen atoms of two nitrogen containing five-membered rings, respectively; and
at least four carbon-hydrogen bonds in the first aryl group and the second aryl group are replaced by carbon-diplogen bonds.

7. The luminescent layer according to claim 4, wherein the second six-membered ring and the fifth six-membered ring comprise a benzene ring;
the first six-membered ring, the third six-membered ring, the fourth six-membered ring and the sixth six-membered ring individually and independently comprise at least one of a benzene ring, a benzene ring having a side chain, a nitrogen containing heterocycle having no substituent group, and a nitrogen containing heterocycle having the side chain; and
at least one carbon-hydrogen bond in the side chain is replaced by a carbon-diplogen bond.

8. The luminescent layer according to claim 7, wherein the indole-carbazole-type derivative further comprises a first aryl group and a second aryl group, and the first aryl group and the second aryl group are bonded to nitrogen atoms of two nitrogen containing five-membered rings, respectively; and
at least four carbon-hydrogen bonds in the first aryl group, the second aryl group and the side chain are replaced by carbon-diplogen bonds.

9. The luminescent layer according to claim 5, wherein a general structural formula of the indole-carbazole-type derivative is: 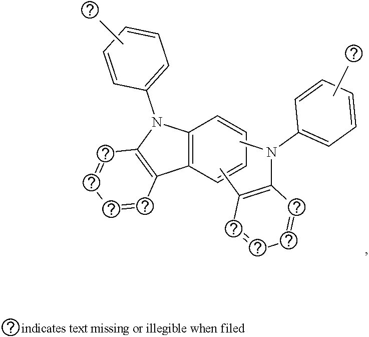
wherein X1-X8 are independently any one of carbon-diplogen, carbon-R3 and nitrogen, wherein R3 is any one of phenyl, biphenyl, naphthyl, carbazole, dibenzofuran, dibenzothiophene, dimethyl fluorene, diphenyl fluorene, and C1-C10 alkyl;
R1 and R2 are independently any one of a single bond, phenyl, biphenyl, naphthyl, carbazole, dibenzofuran, dibenzothiophene, dimethyl fluorene, diphenyl fluorene, and C1-C10 alkyl; and
m and n are independently any one of 0, 1 and 2.

10. The luminescent layer according to claim 9, wherein 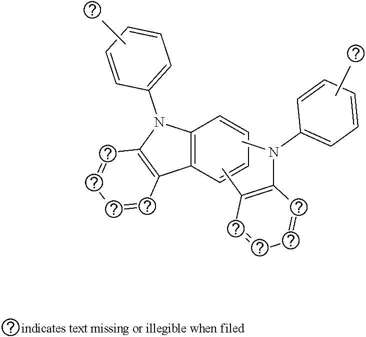
comprises any one of

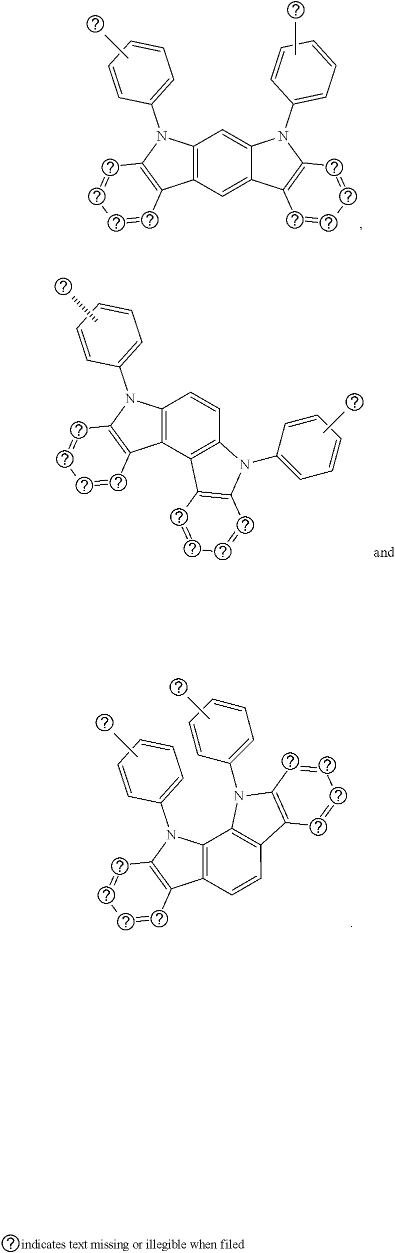

11. The luminescent layer according to claim 10, wherein both of an energy value of a highest occupied molecular orbital HOMO of the 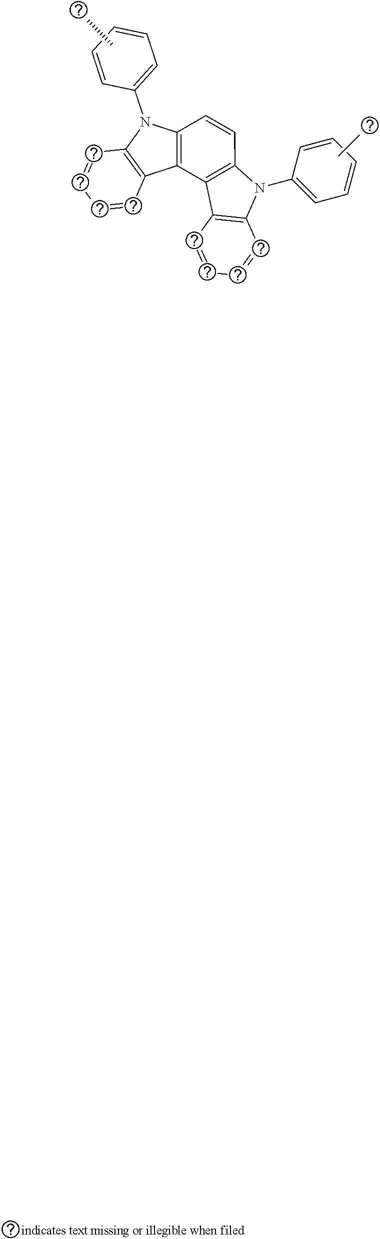
and an energy value of a highest occupied molecular orbital HOMO of the 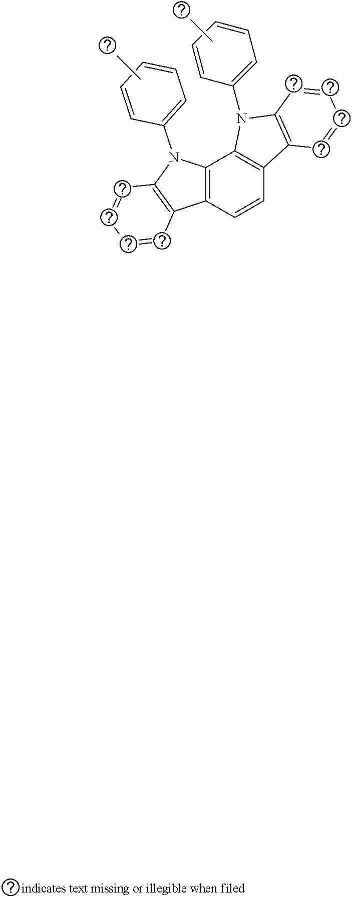
are less than an energy value of a highest occupied molecular orbital HOMO of the

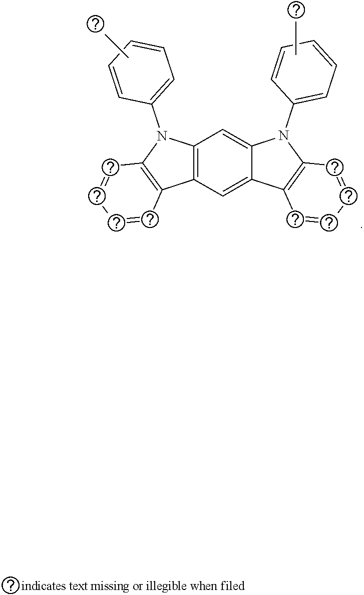

12. The luminescent layer according to claim 10, wherein in the 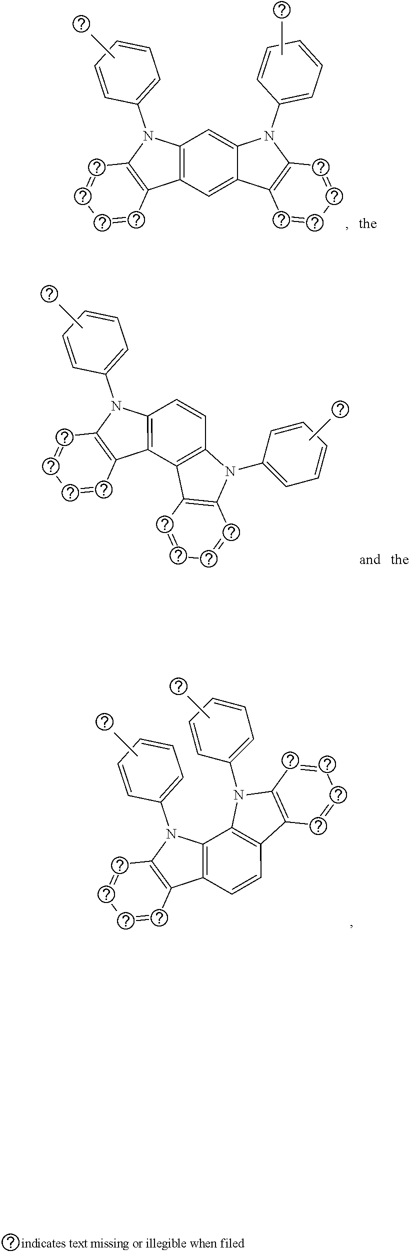
in any one of the general structural formulas, if all of the other groups are the same, an energy value of a highest occupied molecular orbital HOMO of a structure having the side chain is greater than an energy value of a highest occupied molecular orbital HOMO of a structure not having the side chain.

13. The luminescent layer according to claim 10, wherein neighboring X groups in X1-X8 are fused to form any one of 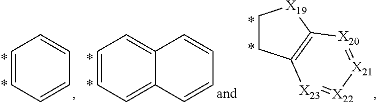
wherein * is a fusing position;
X19 is any one of carbon-R4R5, oxygen, sulphur and nitrogen-R6;
X24 and X29 are independently any one of oxygen, sulphur and nitrogen-R7; and
X20-X23 are independently any one of carbon-R8 and nitrogen;
wherein R4, R5, R6 and R8 are independently any one of a single bond, phenyl, biphenyl, naphthyl, carbazole, dibenzofuran, dibenzothiophene, dimethyl fluorene, diphenyl fluorene, and C1-C10 alkyl; and
R7 is phenyl.

14. The luminescent layer according to claim 4, wherein a general structural formula of the triazine-type derivative is: 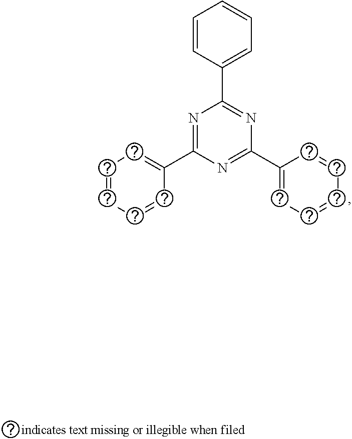 [SMILES: c1ccc(-c2nc(-c3ccccc3)nc(-c3ccccc3)n2)cc1]
wherein X9-X18 are independently any one of carbon-diplogen, carbon-R7 and nitrogen, wherein R7 is phenyl.

15. The luminescent layer according to claim 14, wherein in the general structural formula of the triazine-type derivative, if all of the other groups are the same, an energy value of a lowest unoccupied molecular orbital LUMO of a structure having the side chain is less than an energy value of a lowest unoccupied molecular orbital LUMO of a structure not having the side chain.

16. The luminescent layer according to claim 14, wherein neighboring X groups in X9-X18 are fused to form any one of 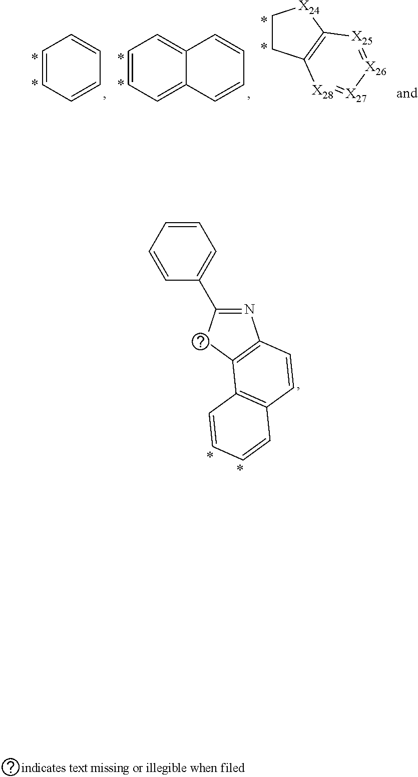
wherein * is a fusing position;
X24 and X29 are independently any one of oxygen, sulphur and nitrogen-R7; and
X25-X28 are independently any one of carbon-R8 and nitrogen;
wherein R8 is any one of a single bond, phenyl, biphenyl, naphthyl, carbazole, dibenzofuran, dibenzothiophene, dimethyl fluorene, diphenyl fluorene, and C1-C10 alkyl; and
R7 is phenyl.

17. The luminescent layer according to claim 13, wherein neighboring X groups in X19-X23 and neighboring X groups in X24-X28 are fused to form any one of 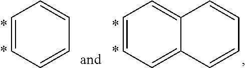 [SMILES: c1ccccc1 ; c1ccc2ccccc2c1]
respectively.

18-19. (canceled)

20. A light emitting device, wherein the light emitting device comprises the luminescent layer according to claim 1.

21. The light emitting device according to claim 20, wherein the light emitting device further comprises an anode and a cathode, and the luminescent layer is disposed between the anode and the cathode.

22. A display apparatus, wherein the display apparatus comprises the light emitting device according to claim 20.
